(19) United States
(12) Patent Application Publication
(10) Pub. No.: US 2016/0293199 A1
(43) Pub. Date: Oct. 6, 2016

(54) METHOD FOR MANUFACTURING MAGNETIC RECORDING MEDIUM

(71) Applicant: FUJI ELECTRIC CO., LTD., Kawasaki-shi (JP)

(72) Inventors: Tomohiro Moriya, Sendai-shi (JP); Takehito Shimatsu, Sendai-shi (JP)

(21) Appl. No.: 15/034,502

(22) PCT Filed: Apr. 20, 2015
(86) PCT No.: PCT/JP2015/002140

§ 371 Date: May 4, 2016

(30) Foreign Application Priority Data
Apr. 24, 2014 (JP) 2014-090078

(51) Int. Cl. G11B 5/84; G11B 5/73; C03C 17/36; C23C 14/08; C23C 14/18; G11B 5/851; C30B 23/08; C30B 23/06; C30B 29/52; C30B 29/02; C30B 29/16; G11B 5/65; C23C 14/34

(52) U.S. Cl. CPC G11B 5/8404; G11B 5/65; G11B 5/731; C03C 17/361; C03C 17/3615; C03C 17/3634; C03C 17/3639; C03C 17/3642; C03C 17/3649; C23C 14/081; C23C 14/18; C23C 14/34; C30B 23/08; C30B 23/066; C30B 29/52; C30B 29/02; C30B 29/16; G11B 5/851; C03C 2217/70; C03C 2218/151; C03C 2218/156; C03C 2218/31

(57) ABSTRACT

The purpose of the present invention is to provide a method for manufacturing a magnetic recording medium including a magnetic recording layer having a larger magnetic anisotropic constant Ku. The method according to the present invention includes the steps of: (a) preparing a substrate; (b) heating the substrate to a temperature of 350° C. or higher, and depositing a non-magnetic material containing MgO as a main component to form a base layer; and (c) forming a magnetic recording layer onto the base layer.

### TECHNICAL FIELD

The invention some constitutional examples of which are described in the specification relates to a method for manufacturing a magnetic recording medium. Particularly, it relates to a method for manufacturing a magnetic recording medium which is used in a hard disc magnetic recording device (HDD). More particularly, it relates to a method for manufacturing a magnetic recording medium suitable to use in a heat-assisted magnetic recording system.

### BACKGROUND ART

Perpendicular magnetic recording system is adopted as a technique for increasing the magnetic recording density. A perpendicular magnetic recording medium at least comprises a non-magnetic substrate, and a magnetic recording layer formed of a hard-magnetic material. Optionally, the perpendicular magnetic recording medium may further comprise: a soft-magnetic backing layer formed of a soft magnetic material and playing a role in concentrating the magnetic flux generated by a magnetic head onto the magnetic recording layer; a base layer for orienting the hard-magnetic material in the magnetic recording layer in an intended direction; a protective layer for protecting the surface of the magnetic recording layer; and the like.

It is proposed to use a granular magnetic material to form the magnetic recording layer in the magnetic recording medium, in order to obtain favorable magnetic properties. The granular magnetic material comprises magnetic crystal grains and a non-magnetic body segregated to surround the magnetic crystal grains. Magnetic crystal grains within the granular magnetic material are magnetically separated from each other by the non-magnetic body.

For the purpose of further increasing the recording density of perpendicular magnetic recording medium, an urgent need for reduction in the grain diameter of the magnetic crystal grains in the granular magnetic material arises in recent years. On the other hand, reduction in the grain diameter of the magnetic crystal grains leads to a decrease in thermal stability of the recorded magnetization (signals). In order to compensate for the decrease in thermal stability due to the reduction in the grain diameters of the magnetic crystal grains, the magnetic crystal grains in the granular magnetic material need to be formed of a material with higher magnetocrystalline anisotropy. One of proposed materials having the required higher magnetocrystalline anisotropy is L1₀ type ordered alloys. Typical L1₀ type ordered alloys include FePt, CoPt, FePd, CoPd, and the like.

Excellent crystalline orientation of the L1₀ type ordered alloys is necessary to achieve the higher magnetocrystalline anisotropy with the L1₀ type ordered alloys. As a method for forming a thin film of the L1₀ type ordered alloy having excellent crystalline orientation at a low substrate temperature, Japanese Patent Laid-Open No. 2010-503139 describes the method comprising the steps of: depositing a lower layer consisting of a Cr-based alloy of (002) orientation onto a substrate; depositing a buffer layer of (002) orientation onto the lower layer, and depositing an FePt magnetic recording layer onto the buffer layer at a substrate temperature lower than 400° C., wherein the buffer layer comprises MgO or SrTiO₃, the thickness of the buffer layer is from 2 nm to 8 nm, and the lattice misfit between the lower layer and the magnetic recording layer is from 3% to 10% (see PTL1). Here, the buffer layer comprising MgO is deposited at room temperature or at a substrate temperature from 30° C. to 300° C. However, there is no description about the relationship between the substrate temperature when depositing the buffer layer and the crystal axis orientation dispersion of the magnetic recording layer, at all.

Besides, International Patent Publication No. WO 2011/021652 proposes a method for forming a magnetic recording layer consisting of an L1₀ type ordered alloy onto a base layer which consists of a first layer consisting of an amorphous alloy, a second layer consisting of a Cr alloy having a body-centered cubic (bcc) structure, and a third layer consisting of MgO (see PTL2). The purpose of this proposal is to decrease the particle diameter of the magnetic crystal grains in the magnetic recording layer consisting of the L1₀ type ordered alloy by reducing the crystalline particle diameter of the second layer consisting of the Cr alloy. The third layer consisting of MgO prevents the atoms constituting the Cr alloy of the second layer from migrating into the magnetic recording layer consisting of the L1₀ type ordered alloy in the case where the substrate temperature when forming the magnetic recording layer is higher than 350° C. There is no description about the relationship between the substrate temperature when forming the third layer consisting of MgO and the crystal axis orientation dispersion of the magnetic recording layer formed thereon, at all.

On the other hand, reduction in the sizes of the magnetic crystal grains means reduction in the cross-sectional areas of the crystal magnetic grains having a certain height, since the thickness of the magnetic recording layer is basically uniform in in-plane directions of the medium. As a result, a diamagnetic field acting on the magnetic crystal grains themselves decreases, whereas a magnetic field required reversing the magnetization of the magnetic crystal grains (magnetic switching field) increases. As described above, the improvement of the recording density implies that a larger magnetic field is required for recording signals, in view of the shape of the magnetic crystal grains.

Energy-assisted magnetic recording systems such as a heat-assisted recording system or a microwave-assisted recording system have been proposed as the other means against the problem of increase in the magnetic field strength required for recording (see NPL1). The heat-assisted recording system utilizes the temperature dependence of the magnetic anisotropy constant (Ku) of a magnetic material, which is a characteristic where the higher the temperature, the lower the Ku. This system uses a head having a function to heat a magnetic recording layer. That is, writing is conducted while the temperature of the magnetic recording layer is raised to temporarily reduce the Ku and thereby reducing the magnetic switching field. The recorded signals (magnetization) can be maintained stably, since the Ku returns its original high value after the temperature of the magnetic recording layer drops. In the application of the heat-assisted system, it is necessary to design a magnetic recording layer, taking its temperature characteristics into consideration in addition to the conventional design guidelines.

### CITATION LIST

### Patent Literature

PTL1: Japanese Patent Laid-Open No. 2010-503139

PTL2: International Patent Publication No. WO 2011/021652

### Non Patent Literature

NPL1: Inaba et al., “New High Density Recording Technology: Energy Assisted Recording Media”, Fuji Electric Journal, R&D Headquarters of Fuji Electric Co., Ltd., July 10, 2010, Vol. 83, Issue 4, pp. 257-260

NPL2: R. F. Penoyer, “Automatic Torque Balance for Magnetic Anisotropy Measurements”, The Review of Scientific Instruments, August 1959, Vol. 30, No. 8, pp. 711-714

NPL3: Soshin Chikazumi, “Physics of ferromagnetism Vol. II”, Shokabo Co., Ltd., pp. 10-21

### SUMMARY OF INVENTION

### Technical Problem

The problem to be solved by the invention some constitutional examples of which are described in the specification is to provide a method for manufacturing a magnetic recording medium comprising a magnetic recording layer having a larger magnetic anisotropy constant Ku.

### Solution to Problem

The method for manufacturing a magnetic recording medium according to one constitutional example of the present invention comprises the steps of: (a) preparing a substrate; (b) heating the substrate to a temperature of 350° C. or higher, and depositing a non-magnetic material comprising MgO as a main component to form a base layer; and (c) forming a magnetic recording layer onto the base layer. Here, the method may further comprise the step of (b′) depositing Cr metal or an alloy having a bcc structure and comprising Cr as a main component, to form a second base layer, prior to the step (b). Further, it is preferable to deposit a material for forming an ordered alloy, in the step (c). Further, it is preferable to deposit a magnetic material for forming magnetic crystal grains and a non-magnetic material for forming a non-magnetic grain boundary which surrounds the magnetic crystal grains, in the step (c).

### Advantageous Effects of Invention

By adopting the above-described configuration, it becomes possible to decrease the crystal axis orientation dispersion, arithmetic average roughness Ra, and maximum height Rz of the base layer onto which the magnetic recording layer is formed, and thereby decreasing the crystal axis orientation dispersion of the magnetic recording layer and increasing the magnetic anisotropy constant Ku of the magnetic recording layer. The magnetic recording medium manufactured by the above-described manufacturing method is suitable to use it in energy-assisted recording systems.

### BRIEF DESCRIPTION OF DRAWINGS

FIG. 1 is a cross-sectional diagram showing a configuration example of the magnetic recording medium obtained by the manufacturing method according to one constitutional example of the present invention;

FIG. 2 is a cross-sectional diagram showing another configuration example of the magnetic recording medium obtained by the manufacturing method according to another constitutional example of the present invention;

FIG. 3 is a graphical representation showing the relationship between the crystal axis orientation dispersion of the base layer obtained in Experimental Example A and the substrate temperature when forming the base layer;

FIG. 4A is an atomic force microscopic (AFM) image of the base layer formed at a surface temperature of 250° C., in Experimental Example A;

FIG. 4B is an AFM image of the base layer formed at a surface temperature of 300° C., in Experimental Example A;

FIG. 4C is an AFM image of the base layer formed at a surface temperature of 350° C., in Experimental Example A;

FIG. 4D is an AFM image of the base layer formed at a surface temperature of 400° C., in Experimental Example A;

FIG. 5 is a graphical representation showing the relationship between the crystal axis orientation dispersion of the magnetic recording layer obtained in Examples 1 and 2 and the substrate temperature when forming the base layer; and

FIG. 6 is a graphical representation showing the relationship between the magnetic anisotropy constant of the magnetic recording layer obtained in Examples 1 and 2 and the substrate temperature when forming the base layer.

### DESCRIPTION OF EMBODIMENTS

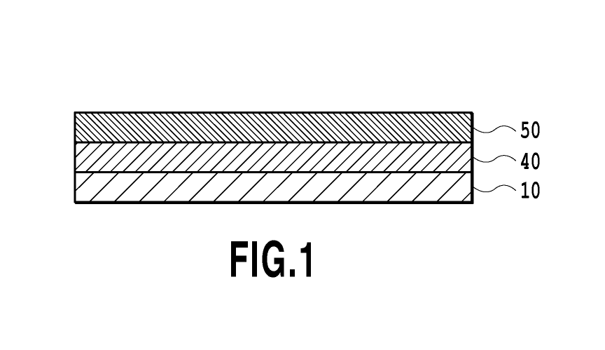

The method for manufacturing a magnetic recording medium according to one constitutional example of the present invention comprises the steps of: (a) preparing a substrate; (b) heating the substrate to a temperature of 350° C. or higher, and depositing a non-magnetic material comprising MgO as a main component to form a base layer; and (c) forming a magnetic recording layer onto the base layer. FIG. 1 shows a cross-sectional diagram of the magnetic recording medium obtained by the above-described method, the medium comprising non-magnetic substrate 10, base layer 40, and magnetic recording layer 50.

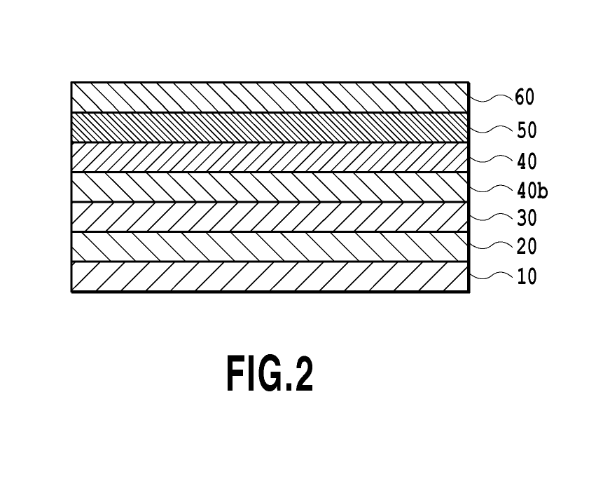

The “substrate” prepared in the step (a) includes the non-magnetic substrate 10. Alternatively, laminated article in which layers commonly known in the art, such as an adhesive layer, a soft-magnetic backing layer, a heat sink layer, a seed layer, and the like, are formed on the non-magnetic substrate 10 can be used as the “substrate” in the step (a). FIG. 2 shows a cross-sectional diagram of the magnetic recording medium comprising the non-magnetic substrate 10, the adhesive layer 20, the seed layer 30, second base layer 40b, the base layer 40, the magnetic recording layer 50, and protective layer 60. In the constitution shown in FIG. 2, the partial structure consisting of the non-magnetic substrate 10, the adhesive layer 20, and the seed layer 30 is considered as the “substrate” in the step (a). The second base layer 40b will be explained later.

The non-magnetic substrate 10 may be various substrates having a flat surface. For example, the non-magnetic substrate 10 may be formed of material commonly used in magnetic recording media. The useful material includes NiP-plated Al alloy, monocrystalline MgO, MgAl₂O₄, SrTiO₃, tempered glass, crystallized glass, and the like.

The adhesive layer 20 that may be formed optionally is used for enhancing the adhesion between the layer formed on the adhesive layer 20 and the layer formed under the adhesive layer 20. The layer formed under the adhesive layer 20 includes the non-magnetic substrate 10. The material for forming the adhesive layer 20 includes a metal such as Ni, W, Ta, Cr or Ru, or an alloy containing the above-described metal. The adhesive layer may be a single layer or have a laminated structure with a plurality of layers.

The soft-magnetic backing layer (not shown) that may be formed optionally controls the magnetic flux emitted from a magnetic head, to improve the read-write characteristics of the magnetic recording medium. The material for forming the soft-magnetic backing layer includes: a crystalline material such as an NiFe alloy, a sendust (FeSiAl) alloy, or a CoFe alloy; a microcrystalline material such as FeTaC, CoFeNi or CoNiP; and an amorphous material including a Co alloy such as CoZrNb or CoTaZr. The optimum thickness of the soft-magnetic backing layer depends on the structure and characteristics of the magnetic head used in magnetic recording. When forming the soft-magnetic backing layer continuously with other layers, the soft-magnetic backing layer preferably has a thickness in a range from 10 nm to 500 nm (both inclusive), in view of productivity.

When using the magnetic recording medium in a heat-assisted magnetic recording system, a heat sink layer (not shown) may be provided. The heat sink layer is a layer for effectively absorbing excess heat of the magnetic recording layer 50 that is generated during heat-assisted magnetic recording. The heat sink layer can be formed of a material having a high thermal conductivity and a high specific heat capacity. Such material includes a Cu simple substance, an Ag simple substance, an Au simple substance, or an alloy material composed mainly of these substances. As used herein, the expression “composed mainly of” means that the content of the concerned material is 50% by weight or more. In consideration of its strength or the like, the heat sink layer can be formed of an Al—Si alloy, a Cu—B alloy or the like. Further, the function of concentrating the perpendicular magnetic field generated by the head, which is the function of the soft-magnetic backing layer, can be imparted to the heat sink layer by forming the heat sink layer of a sendust (FeSiAl) alloy, a soft-magnetic CoFe alloy, or the like. The optimum thickness of the heat sink layer depends on the amount and distribution of heat generated during heat-assisted magnetic recording, as well as the layer configuration of the magnetic recording medium and the thickness of each constituent layer. When forming the heat sink layer continuously with other constituent layers, the heat sink layer preferably has a thickness of 10 nm or more and 100 nm or less, in view of the productivity. The heat sink layer can be formed by any process known in the art, such as a sputtering method or a vacuum deposition method. In the present specification, the term “sputtering method” includes any technique known in the art, such as a DC magnetron sputtering method and RF magnetron sputtering method. Normally, the heat sink layer is formed by the sputtering method. The heat sink layer can be formed directly under the adhesive layer 20, the soft-magnetic backing layer, the seed layer 30, or the like, in view of properties required for the magnetic recording medium.

The seed layer 30 is a layer provided for the purpose of preventing the crystalline structure of the layer formed below from affecting the crystalline orientation and the size of the magnetic crystal grains in the magnetic recording layer 50. In the case where the soft-magnetic backing layer is provided, the seed layer 30 needs to be non-magnetic, in order to prevent the magnetic influence on the soft-magnetic backing layer. The material for forming the seed layer 30 includes oxides such as MgO or SrTiO₃, nitrides such as TiN, metals such as Cr or Ta, a NiW alloy, and Cr-based alloys such as CrTi, CrZr, CrTa, and CrW. The seed layer 30 can be formed by any process known in the art, such as a sputtering method.

Next, the base layer 40 is formed by depositing a non-magnetic material comprising MgO as a main component, in the step (b). The base layer 40 is a layer for controlling the crystalline orientation of the magnetic recording layer which is in contact with the base layer 40, while ensuring adhesion between the seed layer 30 and the magnetic recording layer 50. As used herein, the “non-magnetic material comprising MgO as a main component” means a material comprising 50% by weight or more of MgO. The non-magnetic material can be deposited by any process known in the art, such as a sputtering method.

The substrate is heated to a temperature of 350° C. or higher, when forming the base layer. The heating temperature of the substrate is preferably in a range from 350° C. to 450° C., in view of the factors such as thermal stability of the substrate and the layers which have been formed, variation in crystalline structures of the layers which have been formed, and inhibition of thermomigration. By forming the base layer 40 at the temperature in the above-described range, it becomes possible to reduce the crystal axis orientation dispersion of the base layer 40, and to reduce the arithmetic average roughness Ra and the maximum height Rz of the surface of the base layer 40. Besides, in the present specification, the arithmetic average roughness Ra and maximum height Rz are determined by observation of measurement area of 1 μm by 1 μm by AFM.

Reduction in the crystal axis orientation dispersion of the base layer 40 means that the deposited non-magnetic material has a high crystal axis orientation. Reduction in the crystal axis orientation dispersion of the base layer 40 and reduction in the arithmetic average roughness Ra of the surface of the base layer 40 are effective to improve crystal axis orientation of the magnetic recording layer 50 that is formed on the base layer 40. Especially in the case where the magnetic recording layer 50 comprises an ordered alloy, the reduction in the crystal axis orientation dispersion of the base layer 40 and the reduction in the arithmetic average roughness Ra of the surface of the base layer 40 contribute to improvement in the degree of order of the ordered alloy. Further, reduction in the maximum height Rz of the surface of the base layer make it possible to decrease the flying height of the magnetic head to improve the magnetic recording density, when utilizing the finally obtained magnetic recording medium.

Next, the magnetic recording layer 50 is formed onto the base layer 40, in the step (c).

The magnetic recording layer 50 may comprise an ordered alloy. The ordered alloy may be alloys comprising at least one element selected from the group consisting of Fe and Co, and at least one element selected from the group consisting of Pt, Pd, Au and Ir. Preferable ordered alloy includes L1₀ type ordered alloys selected from the group consisting of Fe Pt, CoPt, FePd and CoPd. The ordered alloy may further comprise at least one element selected from the group consisting of Ni, Mn, Cr, Cu, Ag, Au and Cr, for modification of properties. Desirable modification of properties includes reduction in the temperature required for ordering of the L1₀ type ordered alloy.

Alternatively, the magnetic recording layer 50 may have a granular structure consisting of magnetic crystal grains and a non-magnetic grain boundary which surrounds the magnetic crystal grains. The magnetic crystal grains may comprise the above-described ordered alloy. The non-magnetic grain boundary may comprise oxides such as SiO₂, TiO₂, and ZnO, nitrides such as SiN and TiN, carbon (C), boron (B), and the like.

Further, the magnetic recording layer 50 may comprise a plurality of magnetic layers. Each of the magnetic layers may have a non-granular structure or the granular structure. The magnetic recording layer 50 may have an exchange-coupled composite (ECC) structure, in which bonding layer such as Ru is deposited so as to be sandwiched between the magnetic layers. Further, a second magnetic layer as a continuous layer not including a granular structure (CAP layer) is formed over a magnetic layer having the granular structure.

The magnetic recording layer 50 can be formed by depositing given materials by a sputtering method. When forming the magnetic recording layer comprising the ordered alloy, targets comprising a material for constituting the ordered ally can be used. More particularly, a target comprising the elements for constituting the ordered alloy at a predetermined ratio can be used. Alternatively, the magnetic recording layer 50 may be formed by using a plurality of targets each of which comprises a single element, and adjusting electric powers applied to the respective targets to control the ratio among the elements. When forming the magnetic recording layer 50 having a granular structure, it is possible to use a target comprising a material for constituting the magnetic crystal grains and a material for constituting the non-magnetic grain boundary at a predetermined ratio. Alternatively, the magnetic recording layer 50 may be formed by using a target comprising a material for constituting the magnetic crystal grains and a target comprising a material for constituting the non-magnetic grain boundary, and adjusting electric powers applied to the respective targets to control the constitutional ratio between the magnetic crystal grains and the non-magnetic grain boundary. Here, when constituting the magnetic crystal grains of the ordered alloy, a plurality of targets, each of which separately comprises an element for constituting the ordered alloy, may be used.

If the magnetic recording layer 50 comprises the ordered alloy, heating of the substrate is involved during formation of the magnetic recording layer 50. In this case, the substrate temperature is in a range from 350° C. to 450° C. By adopting the substrate temperature within this range, it becomes possible to improve the degree of order of the ordered alloy in the magnetic recording layer 50.

Optionally, the protective layer 60 may be formed onto the magnetic recording layer 50. The protective layer 60 can be formed of a material that is conventionally used in the field of magnetic recording media. Specifically, the protective layer 60 can be formed of non-magnetic metal such as Pt and Ta, a carbon-based material such as diamond-like carbon, or silicon-based material such as silicon nitride. The protective layer 60 may be a single layer or have a laminated structure. The protective layer 60 of the laminated structure may have a laminated structure of two types of carbon-based material having different characteristics from each other, a laminated structure of metal and a carbon-based material, a laminated structure of two types of metals having different characteristics from each other, or a laminated structure of metallic oxide film and a carbon-based material, for example. The protective layer 60 can be formed by any process known in the art such as a sputtering method or a vacuum deposition method.

Further, optionally, a liquid lubricant layer (not shown) may be formed onto the protective layer 60. The liquid lubricant layer can be formed of a material conventionally used in the field of magnetic recording media, for example, perfluoropolyether-based lubricants or the like. The liquid lubricant layer can be formed by a coating method, for example, a dip-coating method, a spin-coating method, or the like.

The method for manufacturing a magnetic recording medium according to the other constitutional example of the present invention may further comprise the step of (b′) depositing Cr metal or an alloy having a bcc structure and comprising Cr as a main component, to form a second base layer 40b, prior to the step (b). The alloy having a bcc structure and comprising Cr as a main component includes CrTi, CrZr, CrTa, CrW, and the like. The second base layer 40b can be formed by any process known in the art such as a sputtering method or a vacuum deposition method. The second base layer 40b is effective to reduce the crystal axis orientation dispersion of the base layer 40, and thereby reducing the crystal axis orientation dispersion of the magnetic recording layer 50. Deposition of Cr metal or the alloys comprising Cr as a main component can be achieved by any process known in the art, such as sputtering.

It is found that the crystal axis orientation dispersion of the second base layer 40b formed in the step (b′) is reduced by heating of the substrate in the subsequent step (b). Here, the higher the heating temperature of the substrate in the step (b), the lower the crystal axis orientation dispersion of the second base layer 40b. Decrease in the crystal axis orientation dispersion of the second base layer 40b attributes to decrease in the crystal axis orientation dispersion of the magnetic recording layer 50 and to increase in the magnetic anisotropy constant Ku of the magnetic recording layer.

### EXAMPLES

### Experimental Example A

A chemically strengthened glass substrate having a flat surface (N-10 glass substrate manufactured by HOYA CORPORATION) was washed to prepare non-magnetic substrate 10. The washed non-magnetic substrate 10 was brought into an inline-type sputtering device. Then, Ta adhesive layer 20 of a thickness of 5 nm was formed by an RF magnetron sputtering method using a pure Ta target in Ar gas at a pressure of 0.20 Pa. The substrate temperature was room temperature (25° C.) when forming the Ta adhesive layer 20. The sputtering power was 200 W when forming the Ta adhesive layer 20.

Next, MgO seed layer 30 of a thickness of 1 nm was formed by an RF magnetron sputtering method using an MgO target in Ar gas at a pressure of 0.20 Pa. The substrate temperature was room temperature (25° C.) when forming the MgO seed layer 30. The sputtering power was 600 W when forming the MgO seed layer 30.

Next, Cr second base layer 40b of a thickness of 20 nm was formed by an RF magnetron sputtering method using a pure Cr target in Ar gas at a pressure of 0.20 Pa. The substrate temperature was room temperature (25° C.) when forming the Cr second base layer 40b. The sputtering power was 600 W when forming the Cr second base layer 40b.

Next, MgO base layer 40 of a thickness of 10 nm was formed by an RF magnetron sputtering method using an MgO target in Ar gas at a pressure of 0.18 Pa. The substrate temperature was set to 25° C., 250° C., 300° C., 350° C., and 400° C., when forming the MgO base layer 40. The sputtering power was 500 W when forming the MgO base layer 40.

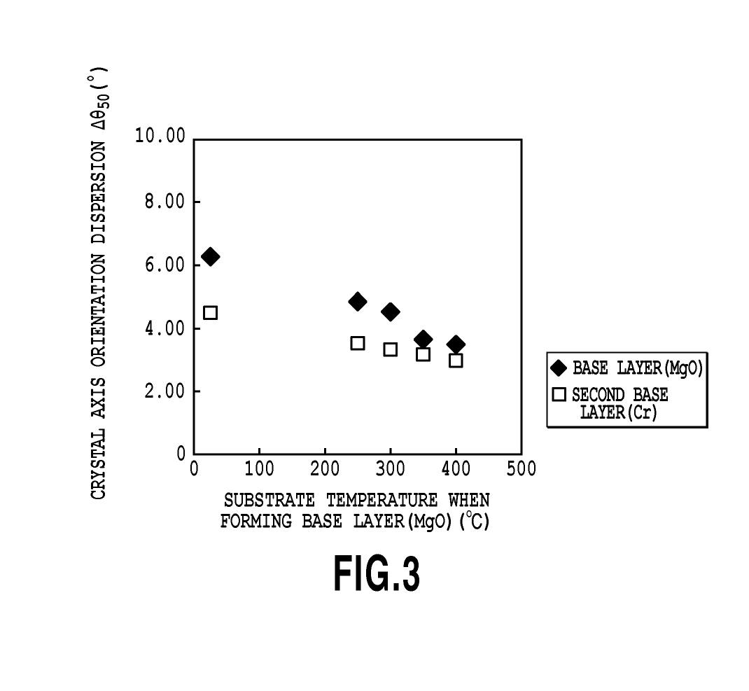

Laminated bodies thus obtained were analyzed by an X-ray diffraction method. As a result, a (002) Cr peak due to the Cr second base layer 40b and a (002) MgO peak due to the MgO base layer 40 were observed. Then, the (002) Cr peak and the (002) MgO peak were analyzed by a rocking curve method, to obtain the crystal axis orientation dispersions Δθ₅₀ of the Cr second base layer 40b and the MgO base layer 40. The rocking curving method is one of measuring techniques for X-ray diffraction, which determine angle of dispersion of a predetermined crystalline face. The measurement was carried out by altering an incident angle (θ) while a detection angle (2θ) was fixed. The Δθ₅₀ was obtained as a full width at half maximum of the obtained peak. The measurement results were shown in FIG. 3 and Table 1.

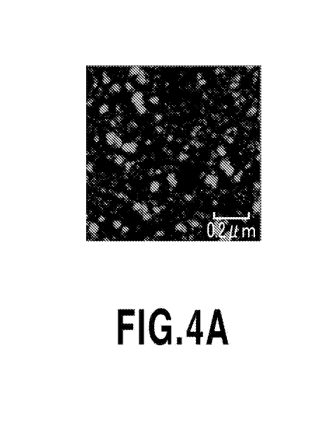

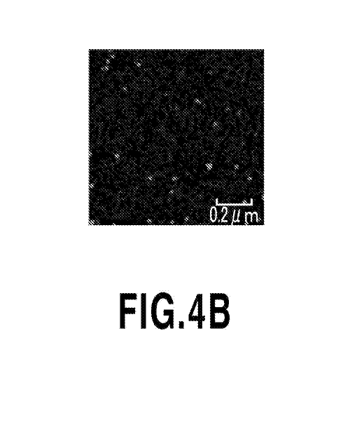

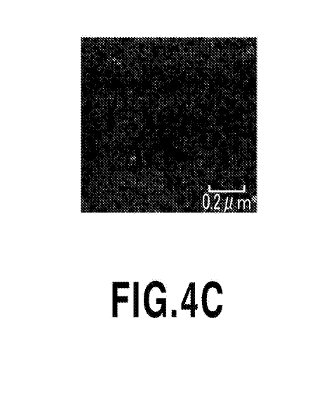

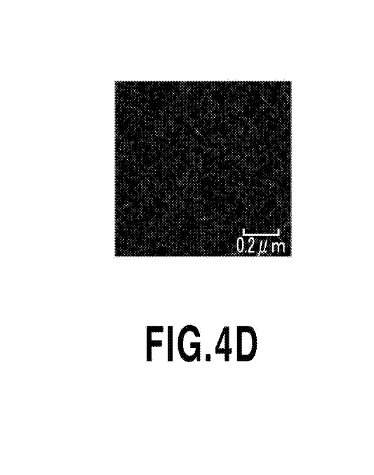

The arithmetic average roughness Ra and the maximum height Rz of the MgO base layer 40, which was a topmost layer of the obtained laminated bodies, were measured by an AFM. In the measurement, the dimensions of a measurement area were set to 1 μm by 1 μm. Further, two measurement areas per sample were measured, and the arithmetic average roughness Ra and the maximum height Rz were determined as averages of the measured value, respectively. The measurement results were shown in Table 1. In addition, the AFM images of the MgO base layers 40 which were formed at the substrate temperatures of 250° C., 300° C., 350° C., and 400° C. were shown in FIGS. 4A-4D, respectively.

TABLE 1
Properties of the laminated bodies of Experimental
Example A

| | | crystal axis | | | |
|---|---|---|---|---|---|
| | substrate | orientation | | | |
| | temperature | dispersion Δθ₅₀ | | arithmetic | |
| | when | (degree) | | average | maximum |
| | forming | | second | roughness | height |
| | base layer | base | base | Ra | Rz |
| sample | (° C.) | layer | layer | (nm) | (nm) |
| A1 | 25 | 6.27 | 4.51 | 2.47 | 20.12 |
| A2 | 250 | 4.85 | 3.51 | 1.345 | 16.573 |
| A3 | 300 | 4.56 | 3.34 | 0.428 | 9.360 |
| A4 | 350 | 3.64 | 3.17 | 0.499 | 8.301 |
| A5 | 400 | 3.50 | 2.97 | 0.463 | 7.234 |

From the results shown in Table 1 and FIG. 3, it is understood that the crystal axis orientation dispersions Δθ₅₀ of the MgO base layer 40 and the Cr second base layer 40b are decreased with the rise in the substrate temperature during the formation of the MgO base layer 40. This feature means improvement in the crystalline orientations of the MgO base layer 40 and the Cr second base layer 40b. In addition, it is understood from the results shown in Table 1 that the arithmetic average roughness Ra of the surface of the MgO base layer 40 decreases when the substrate temperature during formation of the MgO base layer 40 is 300° C. or higher. Further, it is understood from the results shown in FIGS. 4A-4D that generation of irregular protrusions on the surface of the MgO base layer 40 can be suppressed, when the substrate temperature during the formation of the MgO base layer 40 is 350° C. or higher. In FIGS. 4A-4D, regions with white appearance correspond to protrusions having a remarkably great height in comparison with other regions. Many irregular protrusions are observed on the surface of the MgO base layer 40 shown in FIG. 4A, which has been formed at the substrate temperature of 250° C. Several irregular protrusions are observed on the surface of the MgO base layer 40 shown in FIG. 4B, which has been formed at the substrate temperature of 300° C., although the frequency of occurrence is decreased. On the contrary, no irregular protrusions are observed on the MgO base layers 40 shown in FIGS. 4C and 4D, which have been formed at the substrate temperatures of 350° C. and 400° C., respectively. This result is also corroborated by the measurement results of the maximum height Rz shown in Table 1.

### Experimental Example B

A chemically strengthened glass substrate having a flat surface (N-10 glass substrate manufactured by HOYA CORPORATION) was washed to prepare non-magnetic substrate 10. The washed non-magnetic substrate 10 was brought into an inline-type sputtering device. Then, Ta adhesive layer 20 of a thickness of 5 nm was formed by an RF magnetron sputtering method using a pure Ta target in Ar gas at a pressure of 0.20 Pa. The substrate temperature was room temperature (25° C.) when forming the Ta adhesive layer 20. The sputtering power was 200 W when forming the Ta adhesive layer 20.

Next, MgO seed layer 30 of a thickness of 1 nm was formed by an RF magnetron sputtering method using an MgO target in Ar gas at a pressure of 0.20 Pa. The substrate temperature was room temperature (25° C.) when forming the MgO seed layer 30. The sputtering power was 600 W when forming the MgO seed layer 30.

Next, Cr second base layer 40b of a thickness of 20 nm was formed by an RF magnetron sputtering method using a pure Cr target in Ar gas at a pressure of 0.20 Pa. The substrate temperature was room temperature (25° C.) when forming the Cr second base layer 40b. The sputtering power was 600 W when forming the Cr second base layer 40b.

Finally, thus obtained laminated bodies were post-heated for 50 minutes to a temperature of 300° C. or 400° C. The crystal axis orientation dispersion Δθ₅₀ and the arithmetic average roughness Ra of the Cr second seed layer 40b were measured according to the methods similar to those of Experimental Example A, in regard to an unheated laminated body (B1), a 300° C.-post-heated laminated body (B2), and a 450° C.-post-heated laminated body (B3). The measurement results were shown in Table 2.

TABLE 2
Properties of the laminated bodies of
Experimental Example B

| | Second Base Layer | | |
|---|---|---|---|
| | | Crystal axis | Arithmetic |
| | Post-heating | orientation | average |
| | temperature | dispersion | roughness |
| Sample | (° C.) | Δθ₅₀ (deg.) | Ra (nm) |
| B1 | — | 5.19 | 0.207 |
| B2 | 300 | 4.18 | 0.222 |
| B3 | 450 | 2.88 | 0.167 |

In comparison among the samples B1 to B3, it has been understood that the crystal axis orientation dispersion Δθ₅₀ of the Cr second base layer 40b can be reduced by post-heating the Cr second base layer 40b which has been formed at a room temperature. Based on the results of the samples A1-A5, it is understood that the effect of post-heating is obtained by heating the substrate when forming the MgO base layer 40 onto the Cr second base layer. In view of these results, it has been understood that heating the substrate when forming the MgO base layer 40 is effective in not only reducing the crystal axis orientation dispersion Δθ₅₀ of the MgO base layer 40, but also reducing the crystal axis orientation dispersion Δθ₅₀ of the Cr second base layer 40b which has been already formed.

### Example 1

Laminated bodies consisting of the non-magnetic substrate 10, the Ta adhesive layer 20, the MgO seed layer 30, the Cr second base layer 40b, and the MgO base layer 40 was formed by repeating the procedure of Experimental Example A, except that the substrate temperature when forming the MgO base layer 40 was set to 25° C., 300° C., 350° C., 400° C., and 450° C., respectively.

Next, FePt magnetic recording layer 50 of a thickness of 10 nm was formed by an RF sputtering method using an FePt target in Ar gas at a pressure of 1.00 Pa. The substrate temperature was set to 350° C., when forming the FePt magnetic recording layer 50. The sputtering power was 300 W when forming the FePt magnetic recording layer 50.

Finally, protective layer 60, which had a laminated structure of a Pt film of a thickness of 5 nm and a Ta film of a thickness of 5 nm, was formed by an RF sputtering method using a Pt target and a Ta target in Ar gas at a pressure of 0.18 Pa, to obtain magnetic recording media. The substrate temperature was set to a room temperature (25° C.), when forming the protective layer 60. The sputtering power was 300 W when forming the Pt film and the Ta film.

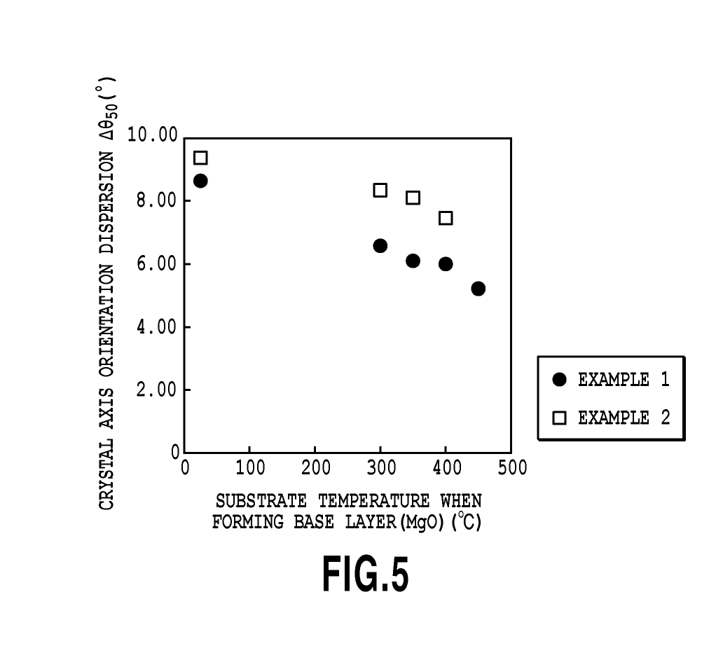

The obtained magnetic recording media were analyzed by an X-ray diffraction method. As a result, a (001) FePt peak and a (002) FePt peak due to the FePt magnetic recording layer 50 were observed. Subsequently, crystal axis orientation dispersion Δθ₅₀ was obtained by analyzing the (002) FePt peak by the rocking curve method. The measurement results were shown in FIG. 5 and Table 3.

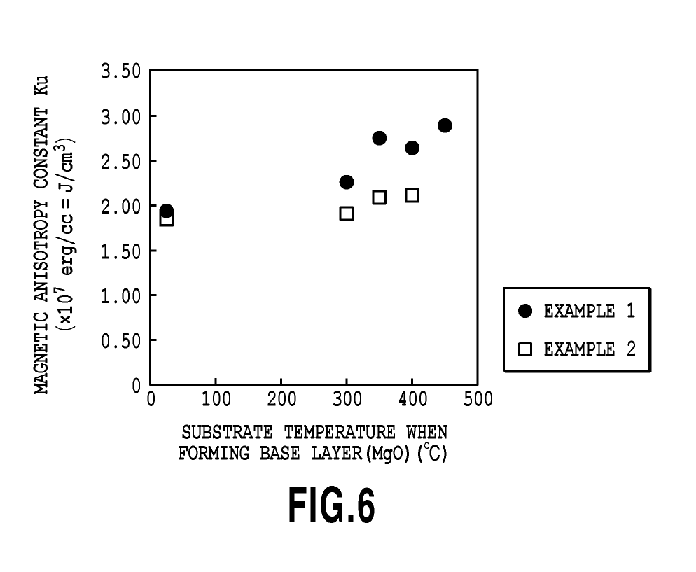

Besides, the magnetic anisotropy constants Ku of the obtained magnetic recording media were determined by evaluating the dependence of spontaneous magnetization on the angle at which the magnetic field is applied, with a PPMS apparatus (Physical Property Measurement System, manufactured by Quantum Design, Inc.). The determination of the magnetic anisotropy constant Ku was in accordance with the method described in the publications of R. F. Penoyer, “Automatic Torque Balance for Magnetic Anisotropy Measurement”, The Review of Scientific Instruments, August 1959, Vol. 30, No. 8, pp. 711-714 and Soshin Chikazumi, “Physics of ferromagnetism Vol. II”, Shokabo Co., Ltd., pp. 10-21 (see NPL2 and NPL3). The measurement results were shown in FIG. 6 and Table 3.

TABLE 3
Properties of the magnetic recording media of
Example 1

| | | | Magnetic |
|---|---|---|---|
| | Substrate | | Anisotropy |
| | temperature | Crystal axis | Constant |
| | when forming | orientation | Ku |
| | base layer | dispersion | (×10⁷ erg/cc, |
| Sample | (° C.) | Δθ₅₀ (deg.) | J/cm³) |
| 1 | 25 | 8.65 | 1.93 |
| 2 | 300 | 6.58 | 2.25 |
| 3 | 350 | 6.10 | 2.74 |
| 4 | 400 | 6.00 | 2.63 |
| 5 | 450 | 5.22 | 2.88 |

In comparison among the samples 1 to 5, it is understood that the crystal axis orientation dispersion Δθ₅₀ of the FePt magnetic recording layer, which is formed on the MgO base layer 40, is reduced by raising the substrate temperature when forming the MgO base layer 40 to 300° C. or higher. It is considered that this feature is caused by decrease in the crystal axis orientation dispersions Δθ₅₀ of the Cr second base layer 40b and the MgO base layer 40 and decrease in the arithmetic average roughness Ra and the maximum height Rz of the surface of the MgO base layer 40, due to the heating during formation of the MgO base layer 40.

In particular, it has been understood that the magnetic anisotropy constant Ku of the FePt magnetic recording layer 50 becomes 2.5×10⁷ erg/cc (2.5 J/cm³) or larger by raising the substrate temperature when forming the MgO base layer to 350° C. or higher. This phenomenon corresponds to the absence of irregular protrusions on the surface of the MgO base layer 40 shown in FIGS. 4C and 4D. This feature makes it possible to reduce the particle diameter of the magnetic crystal grains in the FePt magnetic recording layer 50, and thereby attributing improvement in the recording density of the obtained magnetic recording media. Further, the absence of irregular protrusions on the surface of the MgO base layer 40 attributes a further effect that the obtained magnetic recording media exhibit superior flying properties of the magnetic head.

### Example 2

Laminated bodies consisting of the non-magnetic substrate 10, the Ta adhesive layer 20, the MgO seed layer 30, the Cr second base layer 40b, and the MgO base layer 40 was formed by repeating the procedure of Experimental Example A. The substrate temperature when forming the MgO base layer 40 was set to 25° C., 300° C., 350° C., and 400° C., respectively.

Next, FePt—C magnetic recording layer 50 of a thickness of 4 nm was formed onto the MgO base layer 40 by a co-sputtering method using an FePt target and a C target in Ar gas at a pressure of 1.00 Pa. The volume percentage of C was set to 30% by volume. The substrate temperature was set to 450° C., when forming the FePt—C magnetic recording layer 50. The sputtering power for the FePt target was 150 W, and the sputtering power for the C target was 200 W, when forming the FePt—C magnetic recording layer 50.

Finally, protective layer 60, which had a laminated structure of a Pt film of a thickness of 5 nm and a Ta film of a thickness of 5 nm, was formed by an RF sputtering method using a Pt target and a Ta target in Ar gas at a pressure of 0.18 Pa, to obtain magnetic recording media. The substrate temperature was set to a room temperature (25° C.), when forming the protective layer 60. The sputtering power was 300 W when forming the Pt film and the Ta film.

The crystal axis orientation dispersion Δθ₅₀ of the magnetic recording layer 50 and the magnetic anisotropy constant Ku of the magnetic recording media were evaluated by the same methods as those in Example 1. The measurement results were shown in FIGS. 5 and 6, and Table 4.

TABLE 4
Properties of the magnetic recording media of
Example 2

| | | | Magnetic |
|---|---|---|---|
| | Substrate | | Anisotropy |
| | temperature | Crystal axis | Constant |
| | when forming | orientation | Ku |
| | base layer | dispersion | (×10⁷ erg/cc, |
| Sample | (° C.) | Δθ₅₀ (deg.) | J/cm³) |
| 6 | 25 | 9.38 | 1.84 |
| 7 | 300 | 8.35 | 1.90 |
| 8 | 350 | 8.11 | 2.08 |
| 9 | 400 | 7.46 | 2.10 |

In comparison among the samples 6 to 9, it is understood that, by raising the substrate temperature when forming the MgO base layer 40 to 350° C. or higher, the crystal axis orientation dispersion Δθ₅₀ of the FePt magnetic recording layer, which is formed on the MgO base layer 40, is reduced and the magnetic anisotropy constant Ku is increased, even when the magnetic recording layer has a granular structure.

### REFERENCE SIGNS LIST

10 Non-magnetic substrate

20 Adhesive layer

30 Seed layer

40 Base layer

40b Second base layer

50 Magnetic recording layer

60 Protective layer

1. A method for manufacturing a magnetic recording medium comprising the steps of:
(a) preparing a substrate;
(b) heating the substrate to a temperature of 350° C. or higher and depositing a non-magnetic material comprising MgO as a main component, to form a base layer; and
(c) forming a magnetic recording layer onto the base layer.

2. The method for manufacturing a magnetic recording medium according to claim 1, further comprising the step of:
(b′) depositing Cr metal or an alloy having a bcc structure and comprising Cr as a main component, to form a second base layer,
prior to the step (b).

3. The method for manufacturing a magnetic recording medium according to claim 1, wherein a material for forming an ordered alloy is deposited in the step (c).

4. The method for manufacturing a magnetic recording medium according to claim 1, wherein a magnetic material for forming magnetic crystal grains and a non-magnetic material for forming a non-magnetic grain boundary which surrounds the magnetic crystal grains are deposited in the step (c).

5. The method for manufacturing a magnetic recording medium according to claim 4, wherein the magnetic material comprises a material for forming an ordered alloy.
